(19) United States
(12) Patent Application Publication
(10) Pub. No.: US 2025/0294831 A1
(43) Pub. Date: Sep. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yuta SATO, Himeji Hyogo (JP); Takashi ISHIKAWA, Tatsuno Hyogo (JP); Koji ONISHI, Ibo Hyogo (JP)

(21) Appl. No.: 18/827,504

(22) Filed: Sep. 6, 2024

(30) Foreign Application Priority Data
Mar. 14, 2024 (JP) 2024-040229

(51) Int. Cl. H01L 29/06; H01L 29/10; H01L 29/417

(52) U.S. Cl. CPC H10D 62/127; H10D 62/393; H10D 64/252

(57) ABSTRACT

According to one embodiment, a semiconductor device includes first and second electrodes, first to fifth semiconductor regions, and first and second conductive portions. The first semiconductor region includes a first portion and a second portion located around the first portion. The second semiconductor region is provided on the first portion. The first conductive portion faces the second semiconductor region via a first insulating layer. The fourth semiconductor region is provided on the second portion. The second conductive portion faces the fourth semiconductor region via a second insulating layer. A lower end of the second conductive portion is positioned lower than a lower end of the first conductive portion. The fifth semiconductor region is provided between the second portion and the lower end of the second conductive portion. An impurity concentration of the first conductivity type in the fifth semiconductor region is greater than the one in the second portion.

### CROSS-REFERENCE TO RELATED APPLICATIONS

This application is based upon and claims the benefit of priority from Japanese Patent Application No. 2024-040229, filed on Mar. 14, 2024; the entire contents of which are incorporated herein by reference.

### FIELD

Embodiments of the present invention generally relate to a semiconductor device.

### BACKGROUND

Semiconductor devices such as metal oxide semiconductor field effect transistors (MOSFETs) are used for power conversion and other applications. It is desirable that the breakdown capability of the semiconductor device is high.

### BRIEF DESCRIPTION OF THE DRAWINGS

FIG. 1 is a plan view illustrating a semiconductor device according to an embodiment;

FIG. 2 is an enlarged perspective cross-sectional view of Part II of FIG. 1;

FIG. 3 is a III-III cross-sectional view of FIG. 1;

FIGS. 4A and 4B are cross-sectional views illustrating a method for manufacturing the semiconductor device according to the embodiment;

FIGS. 5A and 5B are cross-sectional views illustrating the method for manufacturing the semiconductor device according to the embodiment;

FIG. 6 is a cross-sectional view illustrating the method for manufacturing the semiconductor device according to the embodiment;

FIG. 7 is an enlarged cross-sectional view of a part of FIG. 3;

FIG. 8 is a cross-sectional view illustrating a part of a semiconductor device according to a modification of the embodiment; and

FIG. 9 is an enlarged cross-sectional view of a part of FIG. 8.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a first conductive portion, a fourth semiconductor region of the second conductivity type, a second conductive portion, a fifth semiconductor region of the first conductivity type, and a second electrode. The first semiconductor region is provided on the first electrode. The first semiconductor region includes a first portion and a second portion located around the first portion along a first plane that is perpendicular to a first direction from the first electrode toward the first semiconductor region. The second semiconductor region is provided on the first portion. The third semiconductor region is provided on the second semiconductor region. The first conductive portion faces the second semiconductor region via a first insulating layer in a second direction that is perpendicular to the first direction. The fourth semiconductor region is provided on the second portion. The second conductive portion faces the fourth semiconductor region via a second insulating layer in the second direction. A lower end of the second conductive portion is positioned lower than a lower end of the first conductive portion. The fifth semiconductor region is provided between the second portion and the lower end of the second conductive portion. An impurity concentration of the first conductivity type in the fifth semiconductor region is greater than an impurity concentration of the first conductivity type in the second portion. The second electrode is provided on the second semiconductor region, the third semiconductor region, and the fourth semiconductor region.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n, n⁻ and p, p⁻ represent relative heights of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative height of a net impurity concentration after mutual compensation of these impurities when respective regions include both of a p-type impurity and an n-type impurity.

The embodiments described below may be implemented by reversing the p-type and the n-type of the semiconductor regions.

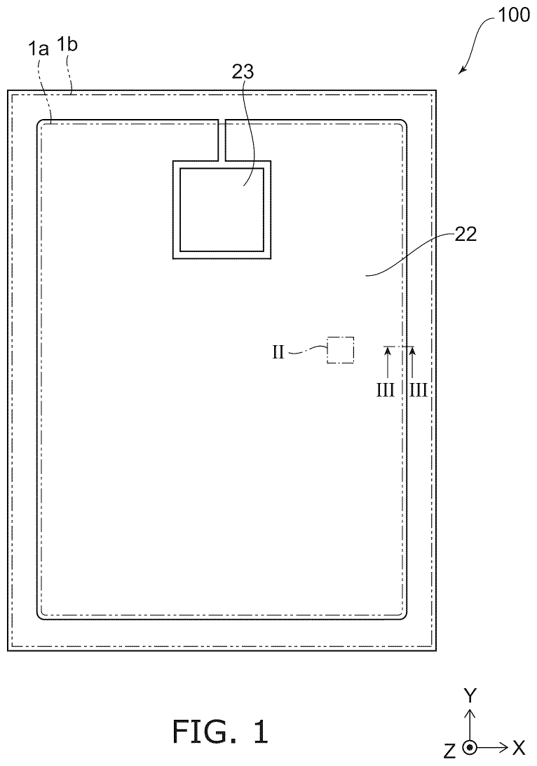

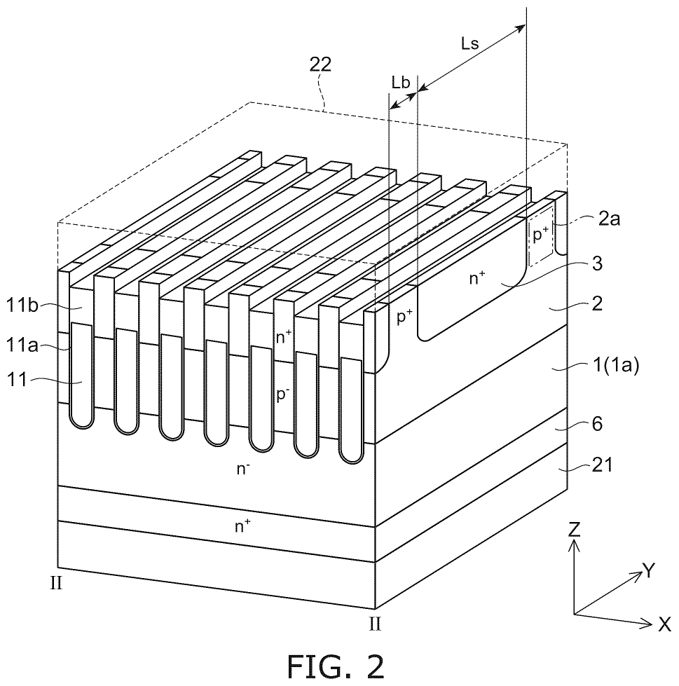

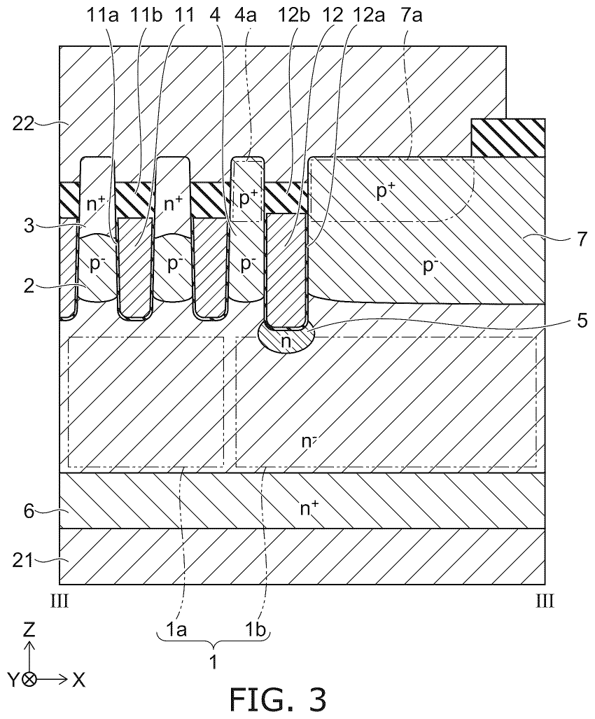

FIG. 1 is a plan view illustrating a semiconductor device according to an embodiment. FIG. 2 is an enlarged perspective cross-sectional view of Part II of FIG. 1. FIG. 3 is a III-III cross-sectional view of FIG. 1.

The semiconductor device 100 according to the embodiment is a MOSFET. As shown in FIGS. 1 to 3, the semiconductor device 100 includes an n⁻-type (a first conductivity type) drift region 1 (a first semiconductor region), a p⁻-type (a second conductivity type) base region 2 (a second semiconductor region), an n⁺-type source region 3 (a third semiconductor region), and a p⁻-type semiconductor region 4 (a fourth semiconductor region), an n-type semiconductor region 5 (a fifth semiconductor region), an n⁺-type drain region 6, a p⁻-type semiconductor region 7, a first conductive portion 11, a first insulating layer 11a, a second conductive portion 12, a second insulating layer 12a, a drain electrode 21 (a first electrode), a source electrode 22 (a second electrode), and a gate pad 23. In FIG. 2, the source electrode 22 is shown by a dashed line.

An XYZ orthogonal coordinate system is used in the description of the embodiments. A direction from the drain electrode 21 toward the n⁻-type drift region 1 is taken as a Z-direction (a first direction); and two mutually-orthogonal directions perpendicular to the Z-direction are taken as an X-direction (a second direction) and a Y-direction (a third direction). In the description, the direction from the drain electrode 21 toward the n⁻-type drift region 1 is called “up/upward/higher than”, and the opposite direction is called “down/downward/lower than”. These directions are based on the relative positional relationship between the drain electrode 21 and the n⁻-type drift region 1, and are independent of the direction of gravity.

As shown in FIG. 1, the source electrode 22 and the gate pad 23 are provided on the upper surface of the semiconductor device 100. The source electrode 22 and the gate pad 23 are separated from each other and electrically isolated.

As shown in FIG. 2, the drain electrode 21 is provided on the lower surface of the semiconductor device 100. The n⁺-type drain region 6 is provided on the drain electrode 21 and is electrically connected to the drain electrode 21. The n⁻-type drift region 1 is provided on the n⁺-type drain region 6. The n⁻-type drift region 1 is electrically connected to the drain electrode 21 via the n⁺-type drain region 6. The n-type impurity concentration in the n⁻-type drift region 1 is less than the n-type impurity concentration in the n⁺-type drain region 6.

The n⁻-type drift region 1 includes the first portion 1a and the second portion 1b as shown in FIGS. 1 to 3. The second portion 1b is located around the first portion 1a in the X-Y plane (a first plane). The first portion 1a is located in a cell region. The cell region is the region through which a current mainly flows during the operation of the semiconductor device 100. The second portion 1b is located in a termination region. The termination region is the region where a depletion layer spreads toward the outer periphery of the semiconductor device 100 when the semiconductor device 100 withstands a voltage.

As shown in FIGS. 2 and 3, the p⁻-type base region 2 is provided on the first portion 1a. The n⁺-type source region 3 is provided on the p⁻-type base region 2. The first conductive portion 11 is provided on the first portion 1a via the first insulating layer 11a. The first conductive portion 11 faces the p⁻-type base region 2 via the first insulating layer 11a in the X-direction.

As shown in FIG. 3, the p⁻-type semiconductor region 4 is provided on the second portion 1b. The second conductive portion 12 is provided on the second portion 1b via a second insulating layer 12a. The second conductive portion 12 faces the p⁻-type semiconductor region 4 via the second insulating layer 12a in the X-direction. The lower end of the second conductive portion 12 is 15 positioned lower than the lower end of the first conductive portion 11.

An n-type semiconductor region such as the n⁺-type source region 3 is not provided on the p⁻-type semiconductor region 4. For example, in the upper part of the p⁻-type semiconductor region 4, at a position aligned with the n⁺-type source region 3 in the X-direction, there is no n-type semiconductor region, and a part of the p⁻-type semiconductor region 4 exists.

The n-type semiconductor region 5 is provided between the second portion 1b and the lower end of the second conductive portion 12. The n-type impurity concentration in the n-type semiconductor region 5 is greater than the n-type impurity concentration in the second portion 1b. It is preferable that the n-type semiconductor region 5 is separated from the p⁻-type semiconductor region 4.

The p⁻-type semiconductor region 7 is provided on the second portion 1b as shown in FIG. 3. The p⁻-type semiconductor region 4 is positioned between the p⁻-type base region 2 and the p⁻-type semiconductor region 7 in the X-direction. The second conductive portion 12 is located between the p⁻-type semiconductor region 4 and the p⁻-type semiconductor region 7 in the X-direction. The length in the X-direction of the p⁻-type semiconductor region 7 is greater than the length in the X-direction of the p⁻-type semiconductor region 4.

The source electrode 22 is provided on the p⁻-type base region 2, the n⁺-type source region 3, the p⁻-type semiconductor region 4, and the p⁻-type semiconductor region 7. The source electrode 22 is electrically connected to the p⁻-type base region 2, the n⁺-type source region 3, the p⁻-type semiconductor region 4, and the p⁻-type semiconductor region 7.

The first conductive portion 11 and the source electrode 22 are electrically isolated from each other by the insulating layer 11b. The second conductive portion 12 and the source electrode 22 are electrically isolated from each other by the insulating layer 12b. The first conductive portion 11 and the second conductive portion 12 are electrically connected to the gate pad 23.

As shown in FIGS. 2 and 3, on the first portion 1a, each of the p⁻-type base region 2, the n⁺-type source region 3, and the first conductive portion 11 is provided in a plurality in the X-direction. The p⁻-type base region 2, the p⁻-type semiconductor region 4, the first conductive portion 11, and the second conductive portion 12 extend in the Y-direction. In the X-direction, multiple p⁻-type base regions 2 and multiple first conductive portions 11 are alternately arranged.

FIG. 3 shows the structure of one end in the X-direction of the semiconductor device 100. The structure on the other end in the X-direction of the semiconductor device 100 is substantially symmetrical with the structure shown in FIG. 3. In other words, one second conductive portion 12 is provided on one end in the X-direction of the semiconductor device 100, and another second conductive portion 12 is provided on the other end in the X-direction of the semiconductor device 100. Multiple p⁻-type base regions 2, multiple n⁺-type source regions 3, and multiple first conductive portions 11 are positioned between the pair of second conductive portions 12 that are separated from each other in the X-direction.

As shown in FIG. 2, the p⁻-type base region 2 may include a contact region 2a having a high p-type impurity concentration. As shown in FIG. 3, the p⁻-type semiconductor region 4 may include a contact region 4a having a high p-type impurity concentration. The p⁻-type semiconductor region 7 may include a contact region 7a having a high p-type impurity concentration. The contact region 2a, the contact region 4a, and the contact region 7a are in contact with the source electrode 22.

As shown in FIG. 2, multiple contact regions 2a and multiple n⁺-type source regions 3 are alternately arranged in the Y-direction on one p⁻-type base region 2. The length Ls in the Y-direction of the n⁺-type source region 3 is greater than the length Lb in the Y-direction of the contact region 2a. The length Lb corresponds to the distance between adjacent n⁺-type source regions 3 in the Y-direction.

The operation of the semiconductor device 100 will now be described. In a state where a positive voltage with respect to the source electrode 22 is applied to the drain electrode 21, a voltage exceeding a threshold is applied to the first conductive portion 11. As a result, a channel (an inversion layer) is formed in the p⁻-type base region 2. Electrons flow from the source electrode 22 to the n⁻-type drift region 1 through the channel; and the semiconductor device 100 is turned on. Thereafter, when the voltage applied to the first conductive portion 11 becomes lower than the threshold, the channel in the p⁻-type base region 2 disappears; and the semiconductor device 100 is turned off. The first conductive portion 11 functions as a gate electrode for controlling the flow of current in the semiconductor device 100.

On the p⁻-type semiconductor region 4, there is no n-type semiconductor region electrically connected to the source electrode 22. Therefore, even when a voltage exceeding the threshold is applied to the second conductive portion 12, no current flows through the inversion layer in the p⁻-type semiconductor region 4.

An example of the material of each component will now be described. The n⁻-type drift region 1, the p⁻-type base region 2, the n⁺-type source region 3, the p⁻-type semiconductor region 4, the n-type semiconductor region 5, the n⁺-type drain region 6 and the p⁻-type semiconductor region 7 include silicon, silicon carbide, gallium nitride, or gallium arsenide as a semiconductor material. When silicon is used as a semiconductor material, arsenic, phosphorus, or antimony can be used as an n-type impurity. As a p-type impurity, boron can be used. The first conductive portion 11 and the second conductive portion 12 include a conductive material such as polysilicon. The first insulating layer 11a, the insulating layer 11b, the second insulating layer 12a, and the insulating layer 12b include an insulating material such as silicon oxide. The drain electrode 21, the source electrode 22, and the gate pad 23 include a metal such as titanium, gold, or aluminum.

Favorable ranges of the impurity concentrations in the semiconductor regions are as follows. The n-type impurity concentration in the n⁻-type drift region 1 is not less than 1.0×10¹⁶ atom/cm³ and not more than 1.0×10¹⁸ atom/cm³. The p-type impurity concentrations in the p⁻-type base region 2, the p⁻-type semiconductor region 4, and the p⁻-type semiconductor region 7 are not less than 1.0×10¹⁷ atom/cm³ and not more than 1.0×10¹⁹ atom/cm³. The n-type impurity concentration in the n⁺-type source region 3 is not less than 5.0×10¹⁸ atom/cm³ and not more than 5.0×10²⁰ atom/cm³. The p-type impurity concentrations in the contact region 2a, the contact region 4a, and the contact region 7a are not less than 5.0×10¹⁸ atom/cm³ and not more than 5.0×10²⁰ atom/cm³. The n-type impurity concentration in the n⁺-type drain region 6 is not less than 1.0×10¹⁹ atom/cm³ and not more than 1.0×10²¹ atom/cm³.

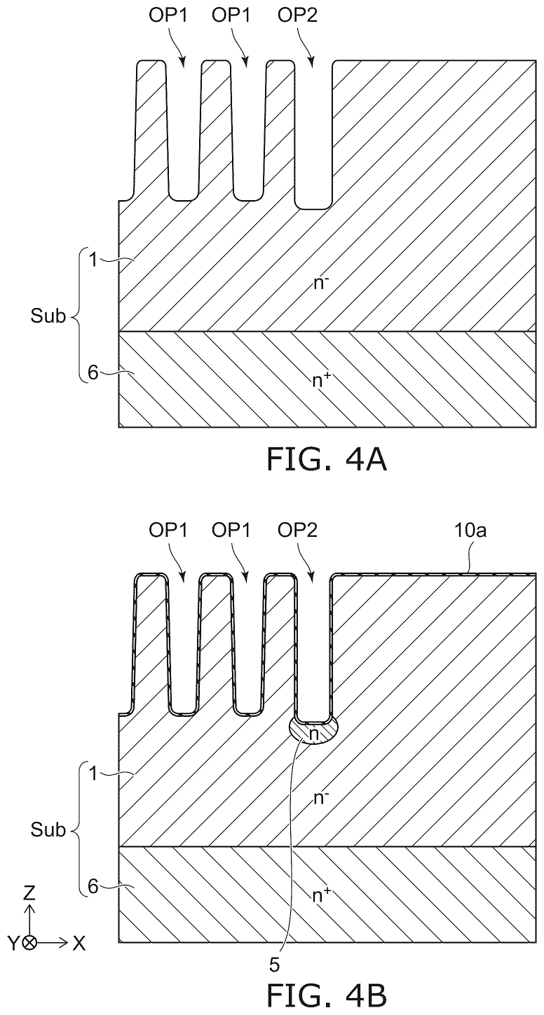

FIGS. 4A, 4B, 5A, 5B, and 6 are cross-sectional views illustrating a method for manufacturing the semiconductor device according to the embodiment.

An example of a method for manufacturing the semiconductor device 100 will now be described. First, a semiconductor substrate Sub including the n⁻-type drift region 1 and the n⁺-type drain region 6 is prepared. As shown in FIG. 4A, multiple openings OP1 are formed on the upper surface of the n⁻-type drift region 1. The multiple openings OP1 are arranged in the X-direction, and each opening OP1 extends in the Y-direction. In addition, an opening OP2 is formed on the upper surface of the n⁻-type drift region 1. The opening OP2 is formed deeper than the opening OP1. The opening OP2 is located within the region where the semiconductor device 100 is to be formed and is positioned outside the multiple openings OP1 within that region.

The semiconductor substrate Sub is thermally oxidized. As a result, an insulating layer 10a is formed on the inner surfaces of the openings OP1, the inner surface of the opening OP2, and the upper surface of the n⁻-type drift region 1. As shown in FIG. 4B, n-type impurities are ion-implanted to the bottom of the opening OP2 to form the n-type semiconductor region 5.

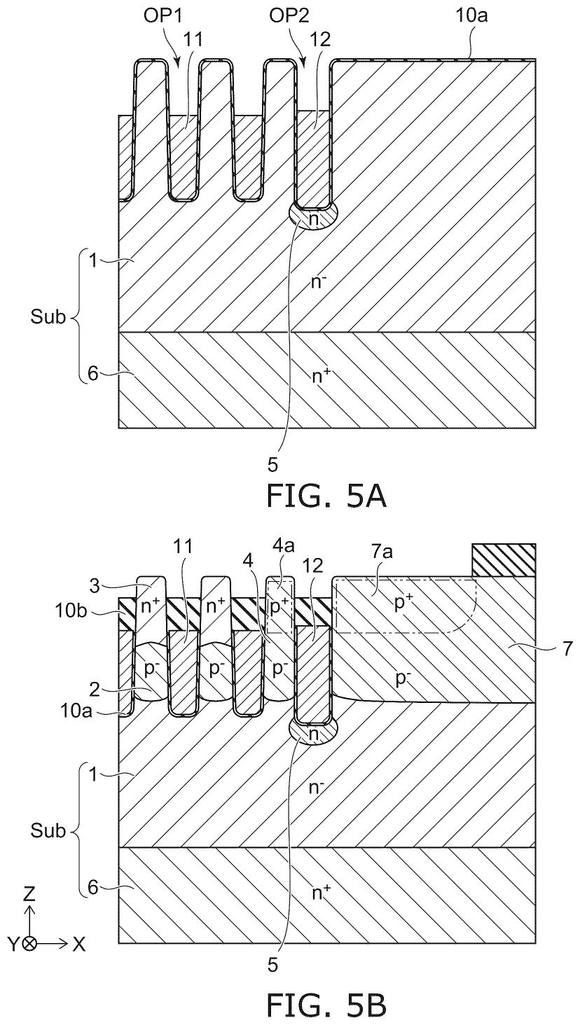

A polysilicon layer filling the openings OP1 and the opening OP2 is formed by chemical vapor deposition (CVD). The upper surface of the polysilicon layer is caused to be retreated by etching. As a result, as shown in FIG. 5A, the first conductive portion 11 is formed inside the opening OP1, and the second conductive portion 12 is formed inside the opening OP2.

P-type impurities and n-type impurities are sequentially ion-implanted into the upper part of the n⁻-type drift region 1 to form the p⁻-type base region 2, the n⁺-type source region 3, the p⁻-type semiconductor region 4, and the p⁻-type semiconductor region 7. An insulating layer 10b covering those semiconductor regions is formed by CVD. As shown in FIG. 5B, the insulating layer 10b and the insulating layer 10a are etched so that the upper surfaces of the n⁺-type source region 3, the p⁻-type semiconductor region 4, and the p⁻-type semiconductor region 7 are exposed.

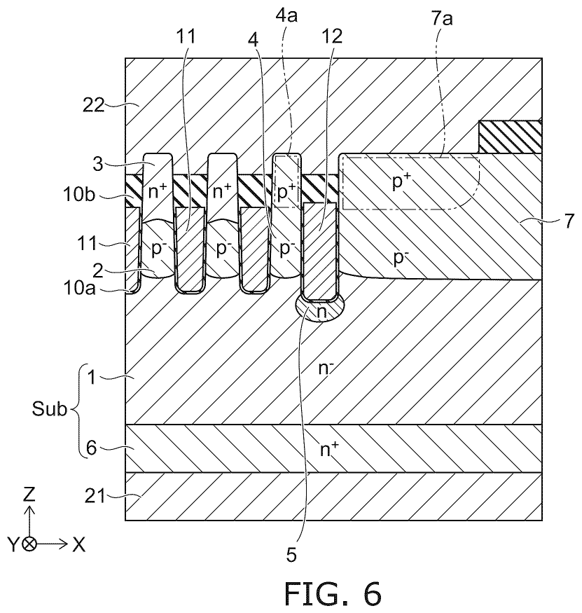

A metal layer is formed by CVD, or sputtering, etc. The metal layer is patterned to form the source electrode 22 and the gate pad 23 (not shown). The lower surface of the n⁺-type drain region 6 is ground until the n⁺-type drain region 6 reaches a predetermined thickness. As shown in FIG. 6, the drain electrode 21 is formed on the ground lower surface of the n⁺-type drain region 6 by sputtering. As described above, the semiconductor device 100 according to the embodiment is manufactured.

Advantages of the embodiment will now be described.

The semiconductor device 100 includes a parasitic transistor consisting of the n⁻-type drift region 1, the p⁻-type base region 2, and the n⁺-type source region 3. When the semiconductor device 100 is turned off, collision ionization (avalanche breakdown) occurs in the semiconductor device 100. Due to collision ionization, a large number of carriers (electrons and holes) are generated. The electrons are discharged through the n⁻-type drift region 1 to the drain electrode 21. The holes are discharged through the p⁻-type base region 2 to the source electrode 22. At this time, when the potential of the p⁻-type base region 2 rises due to the holes, the parasitic transistor may operate. If a large current flows through the semiconductor device 100 due to the operation of the parasitic transistor, there is a possibility that the semiconductor device 100 undergoes breakdown. Therefore, it is desirable that the parasitic transistor is difficult to operate.

The semiconductor device 100 includes the first conductive portion 11 and the second conductive portion 12. When the semiconductor device 100 is turned off, due to the potential difference between the n⁻-type drift region 1 and the first conductive portion 11, and the potential difference between the n⁻-type drift region 1 and the second conductive portion 12, collision ionization occurs in the vicinity of the lower end of the first conductive portion 11, the vicinity of the lower end of the second conductive portion 12, etc. In particular, in the semiconductor device 100, the lower end of the second conductive portion 12 is positioned lower than the lower end of the first conductive portion 11. Therefore, when the semiconductor device 100 is turned off, collision ionization occurs mainly in the vicinity of the lower end of the second conductive portion 12.

When collision ionization occurs in the vicinity of the lower end of the second conductive portion 12, the holes mainly flow to the p⁻-type semiconductor region 4 and the p⁻-type semiconductor region 7. An n-type semiconductor region such as the n⁺-type source region 3 is not provided on the p⁻-type semiconductor region 4 and the p⁻-type semiconductor region 7. At the height (position in the Z-direction) where the n⁺-type source region 3 is provided, there are a part of the p⁻-type semiconductor region 4 and a part of the p⁻-type semiconductor region 7. In other words, there are no parasitic transistors in the region where the p⁻-type semiconductor region 4 and the p⁻-type semiconductor region 7 are provided. By providing the second conductive portion 12, the operation of parasitic transistors in the semiconductor device 100 can be suppressed, and the breakdown capability of the semiconductor device 100 can be improved.

On the other hand, when the lower end of the second conductive portion 12 is positioned lower than the lower end of the first conductive portion 11, the distance between the second conductive portion 12 and the n⁺-type drain region 6 is less than the distance between the first conductive portion 11 and the n⁺-type drain region 6. In the lower region of the second conductive portion 12, the depletion layer easily reaches the n⁺-type drain region 6. As a result, the breakdown voltage of the semiconductor device 100 decreases.

With regard to this issue, in the embodiment, the n-type semiconductor region 5 is provided between the second portion 1b and the second conductive portion 12. The n-type impurity concentration in the n-type semiconductor region 5 is greater than the n-type impurity concentration in the second portion 1b. By providing the n-type semiconductor region 5, the spread of the depletion layer in the lower region of the second conductive portion 12 is suppressed. Therefore, a decrease in the breakdown voltage of the semiconductor device 100 can be suppressed.

According to the embodiment, the breakdown capability of the semiconductor device 100 can be improved while suppressing a decrease in the breakdown voltage of the semiconductor device 100.

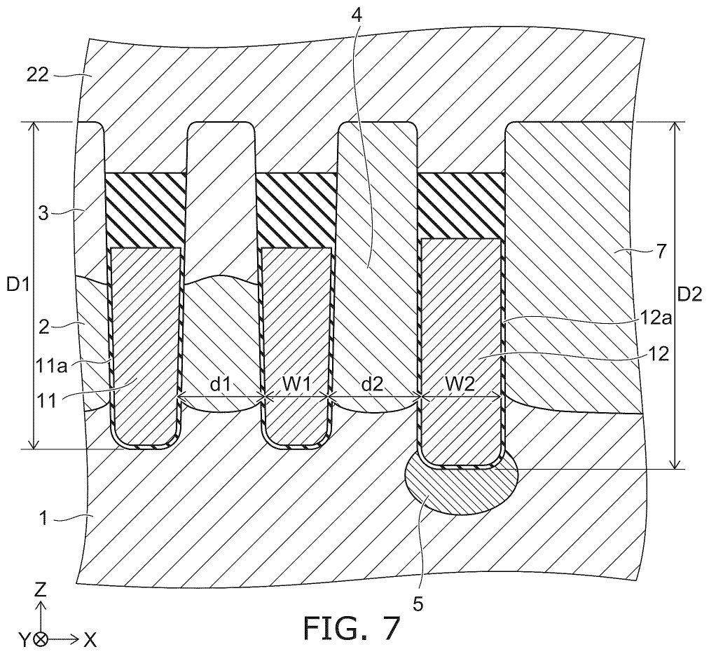

FIG. 7 is an enlarged cross-sectional view of a part of FIG. 3.

The width W2 of the second conductive portion 12 may be the same as the width W1 of the first conductive portion 11. Alternatively, as shown in FIG. 7, the width W2 of the second conductive portion 12 may be greater than the width W1 of the first conductive portion 11. The width is the length in the X-direction. When the width W2 is greater than the width W1, collision ionization occurs more easily in the vicinity of the lower end of the second conductive portion 12. Therefore, the breakdown capability of the semiconductor device 100 can be further improved. For example, the width W2 is preferably not less than 1.01 times and not more than 3 times the width W1, and more preferably not less than 1.02 times and not more than 2 times the width W1. When the width of the first conductive portion 11 or the second conductive portion 12 varies in the Z-direction, the width W1 or width W2 is measured at the height at which the p-n junction between the n⁻-type drift region 1 and the p⁻-type base region 2 exists.

As described above, the lower end of the second conductive portion 12 is positioned lower than the lower end of the first conductive portion 11. For example, the depth D2 of the second conductive portion 12 is greater than the depth D1 of the first conductive portion 11. The depth D1 corresponds to the distance in the Z-direction from the upper surface of the n⁺-type source region 3 to the lower end of the first conductive portion 11. The depth D2 corresponds to the distance in the Z-direction from the upper surface of the p⁻-type semiconductor region 4 to the lower end of the second conductive portion 12. The greater the depth D2, the more easily collision ionization occurs in the vicinity of the lower end of the second conductive portion 12. On the other hand, if the depth D2 is excessively long, the breakdown voltage of the semiconductor device 100 may decrease even when the n-type semiconductor region 5 is provided. For example, the depth D2 is preferably not less than 1.01 times and not more than 1.3 times the depth D1, and more preferably not less than 1.02 times and not more than 1.2times the depth D1.

The distance d2 may be the same as the distance d1 or greater than the distance d1. The distance d1 is the distance between adjacent first conductive portions 11 in the X-direction. The distance d2 is the distance in the X-direction between the second conductive portion 12 and the first conductive portion 11 adjacent to the second conductive portion 12. The distance d2 may be different from the distance d1 or the same as the distance d1. The difference between the distance d1 and the distance d2 is preferably small. If the distance d2 is excessively shorter than the distance d1, the width of the p⁻-type semiconductor region 4 becomes smaller, and holes are difficult to be discharged from the p⁻-type semiconductor region 4. If the distance d2 is excessively greater than the distance d1 and the second conductive portion 12 is away from the first conductive portion 11, collision ionization easily occurs in the vicinity of the lower end of the first conductive portion 11. For example, the distance d2 is preferably not less than 0.78 times and not more than 1.5 times the distance d1, and more preferably not less than 0.85 times and not more than 1.2 times the distance d1. Most preferably, the distance d1 and the distance d2 are the same. When the distance d1 or distance d2 varies in the Z-direction, the distance d1 or the distance d2 is measured at the height at which the p-n junction between the n⁻-type drift region 1 and the p⁻-type base region 2 exists.

The greater the n-type impurity concentration in the n-type semiconductor region 5, the more the spread of the depletion layer in the lower region of the second conductive portion 12 can be suppressed. On the other hand, if the n-type impurity concentration in the n-type semiconductor region 5 is excessively high, the electric field is concentrated in the vicinity of the n-type semiconductor region 5, and the breakdown voltage of the semiconductor device 100 may decrease. Therefore, the n-type impurity concentration in the n-type semiconductor region 5 is preferably not less than 8 times and not more than 300 times the n-type impurity concentration in the n⁻-type drift region 1, and more preferably not less than 10 times and not more than 100 times the n-type impurity concentration in the n⁻-type drift region 1.

### Modification

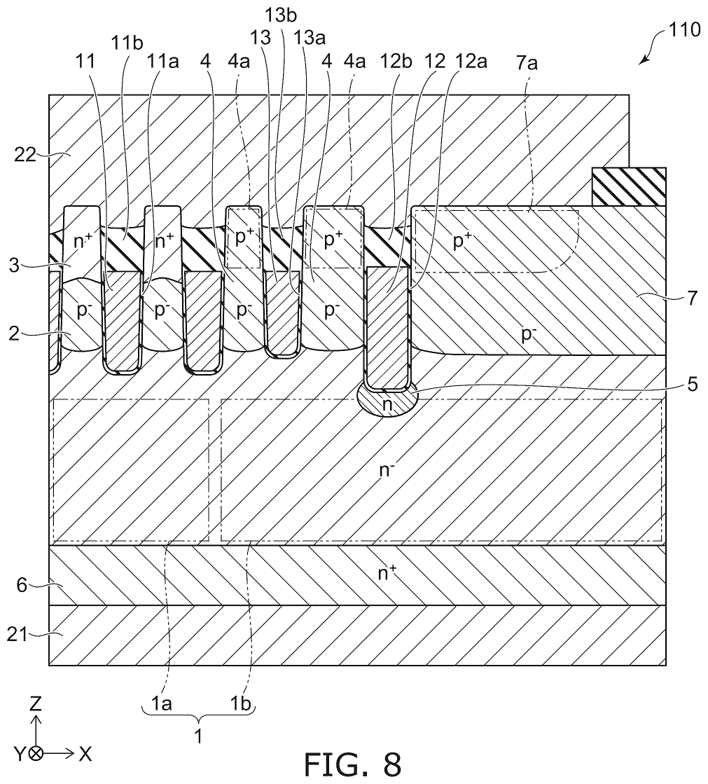

FIG. 8 is a cross-sectional view illustrating a part of a semiconductor device according to a modification of the embodiment.

The semiconductor device 110 shown in FIG. 8 further includes a third conductive portion 13 compared to the semiconductor device 100. The third conductive portion 13 is provided on the second portion 1b. The third conductive portion 13 is positioned between the first conductive portion 11 and the second conductive portion 12 in the X-direction. A p⁻-type semiconductor region 4 is provided between the first conductive portion 11 and the third conductive portion 13. Another p⁻-type semiconductor region 4 is provided between the second conductive portion 12 and the third conductive portion 13. The third conductive portion 13 faces each p⁻-type semiconductor region 4 via a third insulating layer 13a in the X-direction. The third conductive portion 13 and the source electrode 22 are electrically isolated from each other by an insulating layer 13b. The third conductive portion 13 is electrically connected to the gate pad 23.

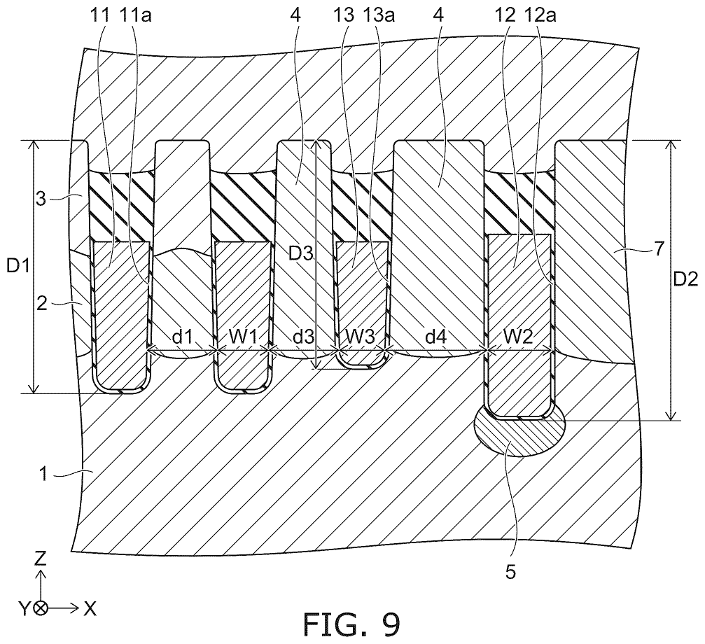

FIG. 9 is an enlarged cross-sectional view of a part of FIG. 8.

As shown in FIG. 9, the lower end of the third conductive portion 13 is positioned higher than the lower end of the second conductive portion 12. The lower end of the third conductive portion 13 may be positioned higher than the lower end of the first conductive portion 11. When the lower end of the third conductive portion 13 is positioned higher than the lower end of the second conductive portion 12, collision ionization is less likely to occur in the vicinity of the lower end of the third conductive portion 13. The third conductive portion 13 is closer to the n⁺-type source region 3 compared to the second conductive portion 12. In other words, the distance between the third conductive portion 13 and the parasitic transistor is shorter than the distance between the second conductive portion 12 and the parasitic transistor. By suppressing collision ionization in the vicinity of the lower end of the third conductive portion 13, the flow of holes generated by collision ionization to the p⁻-type base region 2 can be suppressed. Therefore, the breakdown capability of the semiconductor device 110 can be improved.

The depth D3 of the third conductive portion 13 is less than the depth D1 and less than the depth D2. The depth D3 corresponds to the distance in the Z-direction from the upper surface of the n⁺-type source region 3 to the lower end of the third conductive portion 13. For example, the depth D3 is preferably not less than 0.85 times and not more than 0.99 times the depth D1, and more preferably not less than 0.95 times and not more than 0.99 times the depth D1.

The width W3 of the third conductive portion 13 is less than the width W2. The width W3 may be the same as the width W1, or may be less than the width W1 as illustrated. When the width W3 is less than the width W2, collision ionization is less likely to occur in the vicinity of the lower end of the third conductive portion 13. Therefore, the breakdown capability of the semiconductor device 110 can be further improved. For example, the width W3 is preferably not less than 0.75 times and not more than 0.98 times the width W2, and more preferably not less than 0.85 times and not more than 0.95 times the width W2.

The distance d3 may be the same as the distance d1 or different from the distance d1. The distance d3 is the distance in the X-direction between the third conductive portion 13 and the first conductive portion 11 adjacent to the third conductive portion 13. The difference between the distance d1 and the distance d3 is preferably small. If the distance d3 is excessively less than the distance d1, the width of the p⁻-type semiconductor region 4 becomes smaller, and it becomes difficult for holes to be discharged from the p⁻-type semiconductor region 4. If the distance d3 is excessively greater than the distance d1, collision ionization occurs more easily in the vicinity of the lower end of the first conductive portion 11. For example, the distance d3 is preferably not less than 0.85 times and not more than 1.15 times the distance d1, and more preferably not less than 0.95 times and not more than 1.05 times the distance d1. Most preferably, the distance d1 and the distance d3 are the same.

The distance d4 may be the same as the distance d1 or may be greater than the distance d1 as shown in FIG. 9. In the semiconductor device 110, the lower end of the third conductive portion 13 is positioned higher than the lower end of the first conductive portion 11 and the lower end of the second conductive portion 12. Therefore, in the vicinity of the lower end of the second conductive portion 12 adjacent to the third conductive portion 13, collision ionization occurs more easily compared to the semiconductor device 100. When the distance d4 is long and the width of the p⁻-type semiconductor region 4 is wide, a large number of holes generated by collision ionization can be effectively discharged. For example, the distance d4 is preferably greater than 1.0 times and not more than 1.5 times the distance d1, and more preferably not less than 1.02 times and not more than 1.2 times the distance d1.

Embodiments of the present invention include the following features.

### Feature 1

A semiconductor device including:

a first electrode;

a first semiconductor region of a first conductivity type provided on the first electrode, the first semiconductor region including a first portion and a second portion located around the first portion along a first plane that is perpendicular to a first direction from the first electrode toward the first semiconductor region;

a second semiconductor region of a second conductivity type provided on the first portion;

a third semiconductor region of the first conductivity type provided on the second semiconductor region;

a first conductive portion facing the second semiconductor region via a first insulating layer in a second direction that is perpendicular to the first direction;

a fourth semiconductor region of the second conductivity type provided on the second portion;

a second conductive portion facing the fourth semiconductor region via a second insulating layer in the second direction, a lower end of the second conductive portion being positioned lower than a lower end of the first conductive portion;

a fifth semiconductor region of the first conductivity type provided between the second portion and the lower end of the second conductive portion, an impurity concentration of the first conductivity type in the fifth semiconductor region being greater than an impurity concentration of the first conductivity type in the second portion;

a second electrode provided on the second semiconductor region, the third semiconductor region, and the fourth semiconductor region.

### Feature 2

The semiconductor device according to feature 1, in which

a length in the second direction of the second conductive portion is greater than a length in the second direction of the first conductive portion.

### Feature 3

The semiconductor device according to feature 1 or 2, further including a third conductive portion positioned between the first conductive portion and the second conductive portion in the second direction,

the third conductive portion facing the fourth semiconductor region via a third insulating layer in the second direction.

### Feature 4

The semiconductor device according to feature 3, in which

the lower end of the second conductive portion is positioned lower than a lower end of the third conductive portion.

### Feature 5

The semiconductor device according to feature 4, in which

the lower end of the third conductive portion is positioned higher than the lower end of the first conductive portion.

### Feature 6

The semiconductor device according to any one of features 3 to 5, in which

a length in the second direction of the third conductive portion is less than a length in the second direction of the first conductive portion and less than a length in the second direction of the second conductive portion.

### Feature 7

The semiconductor device according to any one of features 3 to 6, in which

a distance in the second direction between the second conductive portion and the third conductive portion is greater than a distance in the second direction between the first conductive portion and the third conductive portion.

### Feature 8

The semiconductor device according to any one of features 1 to 7, in which

a pair of the second conductive portions separated from each other in the second direction is provided, and

a plurality of the second semiconductor regions and a plurality of the first conductive portions are alternately provided in the second direction and positioned between the pair of second conductive portions.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a first electrode;
a first semiconductor region of a first conductivity type provided on the first electrode, the first semiconductor region including a first portion and a second portion located around the first portion along a first plane that is perpendicular to a first direction from the first electrode toward the first semiconductor region;
a second semiconductor region of a second conductivity type provided on the first portion;
a third semiconductor region of the first conductivity type provided on the second semiconductor region;
a first conductive portion facing the second semiconductor region via a first insulating layer in a second direction that is perpendicular to the first direction;
a fourth semiconductor region of the second conductivity type provided on the second portion;
a second conductive portion facing the fourth semiconductor region via a second insulating layer in the second direction, a lower end of the second conductive portion being positioned lower than a lower end of the first conductive portion;
a fifth semiconductor region of the first conductivity type provided between the second portion and the lower end of the second conductive portion, an impurity concentration of the first conductivity type in the fifth semiconductor region being greater than an impurity concentration of the first conductivity type in the second portion;
a second electrode provided on the second semiconductor region, the third semiconductor region, and the fourth semiconductor region.

2. The semiconductor device according to claim 1, wherein
a length in the second direction of the second conductive portion is greater than a length in the second direction of the first conductive portion.

3. The semiconductor device according to claim 1, further comprising a third conductive portion positioned between the first conductive portion and the second conductive portion in the second direction,
the third conductive portion facing the fourth semiconductor region via a third insulating layer in the second direction.

4. The semiconductor device according to claim 3, wherein
the lower end of the second conductive portion is positioned lower than a lower end of the third conductive portion.

5. The semiconductor device according to claim 4, wherein
the lower end of the third conductive portion is positioned higher than the lower end of the first conductive portion.

6. The semiconductor device according to claim 3, wherein
a length in the second direction of the third conductive portion is less than a length in the second direction of the first conductive portion and less than a length in the second direction of the second conductive portion.

7. The semiconductor device according to claim 3, wherein
a distance in the second direction between the second conductive portion and the third conductive portion is greater than a distance in the second direction between the first conductive portion and the third conductive portion.

8. The semiconductor device according to claim 1, wherein
a pair of the second conductive portions separated from each other in the second direction is provided, and
a plurality of the second semiconductor regions and a plurality of the first conductive portions are alternately provided in the second direction and positioned between the pair of second conductive portions.
